(19) United States
(12) Patent Application Publication
(10) Pub. No.: US 2015/0205212 A1
(43) Pub. Date: Jul. 23, 2015

(54) MASKLESS LIGHT EXPOSURE DEVICE

(71) Applicant: SAMSUNG DISPLAY CO., LTD., YONGIN-CITY (KR)

(72) Inventors: KI-BEOM LEE, SEOUL (KR); HI-KUK LEE, YONGIN-SI (KR); CHA-DONG KIM, SEOUL (KR); CHANG-HOON KIM, ASAN-SI (KR); JUNG-IN PARK, SEOUL (KR); KAB-JONG SEO, SEOUL (KR); JUN-HO SIM, SEOUL (KR); SANG-HYUN YUN, SUWON-SI (KR); JAE-HYUK CHANG, SEONGNAM-SI (KR); HYUN-SEOK KIM, HWASEONG-SI (KR); SANG-HYUN LEE, SUWON-SI (KR)

(21) Appl. No.: 14/322,442

(22) Filed: Jul. 2, 2014

(30) Foreign Application Priority Data
Jan. 23, 2014 (KR) 10-2014-0008172

(51) Int. Cl. G03F 7/20

(52) U.S. Cl. CPC G03F 7/70191

(57) ABSTRACT

A light exposure device is provided. The light exposure device includes a light source, a light modulation part, and a projection optical part. The light modulation part modulates the light based on a predetermined exposure pattern. The projection optical part projects the light from the light modulation part onto a substrate. The projection optical part includes a first optical part, a hole arrangement part, and a second optical part. The first optical part receives the light from the light modulation part. The first optical part includes a plurality of first lenses. The hole arrangement part emits the light from the first optical part. The second optical part emits the light from the hole arrangement part onto the substrate. The second optical part includes a plurality of second lenses. At least one of the first lenses and the second lenses is a transreflective lens.

### CROSS-REFERENCE TO RELATED APPLICATION

This application claims priority under 35 U.S.C. §119 to Korean Patent Application No. 10-2014-0008172, filed on Jan. 23, 2014 in the Korean Intellectual Property Office, the disclosure of which is incorporated by reference herein its entirety.

### TECHNICAL FIELD

The present inventive concept relates to a light exposure device, and more particularly, to a maskless light exposure device.

### DISCUSSION OF THE RELATED ART

A flat display panel such as a liquid crystal display panel, a plasma display panel, etc. may include a substrate on which, for example, a plurality of electrodes, organic materials and inorganic materials are patterned.

Light exposure devices have been developed to form a pattern on the substrate. A portion of the substrate may be selectively exposed by light illumination using, for example, a photo mask. Thus, a chemical feature of material in the portion of the substrate may change due to the exposure of the light and material in the substrate may be selectively removed thereafter by relying on the changed chemical feature.

### SUMMARY

According to an exemplary embodiment of the present inventive concept, a light exposure device is provided. The light exposure device includes a light source, a light modulation part, and a projection optical part. The light source is configured to generate light. The light modulation part is configured to modulate the generated light based on a predetermined exposure pattern. The projection optical part is configured to project the modulated light from the light modulation part onto a substrate as a beam spot array. The projection optical part includes a first optical part, a hole arrangement part, and a second optical part. The first optical part is configured to receive the modulated light from the light modulation part. The first optical part includes a plurality of first lenses. The hole arrangement part is provided between the first optical part and the second optical part and is configured to receive the light from the first optical part and to emit the received light as the beam spot array. The second optical part is configured to receive the light from the hole arrangement part and to emit the received light onto the substrate. The second optical part includes a plurality of second lenses. At least one of the first lenses and the second lenses is a transreflective lens.

In an exemplary embodiment of the present inventive concept, the light modulation part may include a digital micro-mirror device.

In an exemplary embodiment of the present inventive concept, the digital micro-mirror device may include a plurality of micro-mirrors and a pattern generating part. The plurality of micro-mirrors may be arranged in a first direction and a second direction crossing the first direction. The pattern generating part may be configured to control a reflective angle of the micro-mirrors.

In an exemplary embodiment of the present inventive concept, the hole arrangement part may include a micro-lens array and an aperture array. The micro-lens array may include a plurality of micro-lenses corresponding to the micro-mirrors of the digital micro-mirror device and the aperture array may include a plurality of pin holes partially overlapping the micro-lenses.

In an exemplary embodiment of the present inventive concept, each of the pin holes may be greater than about 2 μm and smaller than about 10 μm in size.

In an exemplary embodiment of the present inventive concept, a number of the micro-mirrors may be equal to a number of the micro-lenses.

In an exemplary embodiment of the present inventive concept, each of the first optical part and the second optical part may include a transreflective lens.

In an exemplary embodiment of the present inventive concept, the first optical part may include a first incident lens and a first emitting lens. The first optical part may be configured to receive the modulated light from the light modulation part and to refract the received light. The first emitting lens may be configured to transmit the refracted light toward the hole arrangement part.

In an exemplary embodiment of the present inventive concept, at least one of the first incident lens and the first emitting lens may be a transreflective lens.

In an exemplary embodiment of the present inventive concept, the second optical part may include a second incident lens and a second emitting lens. The second incident lens may be configured to receive the light from the hole arrangement part and to refract the received light. The second emitting lens may be configured to transmit the refracted light toward the substrate.

In an exemplary embodiment of the present inventive concept, at least one of the second incident lens and the second emitting lens may be a transreflective lens.

In an exemplary embodiment of the present inventive concept, the beam spot array may include a plurality of spot beams spaced apart from one another.

In an exemplary embodiment of the present inventive concept, each of the spot beams may have substantially a circular shape having a full width at half maximum in a range between about 1 μm and about 3 μm.

In an exemplary embodiment of the present inventive concept, each of the plurality of spot beams may be spaced apart from one another by a distance in a range between 10 μm and about 100 μm.

In an exemplary embodiment of the present inventive concept, the beam spot array may be tilted with respect to the substrate in a plan view.

In an exemplary embodiment, the light exposure device may further include a light compensation part between the light source and the light modulation part. The light compensation part may be configured to compensate the light from the light source such that the light has a substantially uniform luminance.

In an exemplary embodiment of the present inventive concept, the light exposure device may further include a fixing part and a guiding part. The substrate may be disposed on the fixing part. The guiding part may be configured to move the fixing part in a horizontal or a vertical direction.

In an exemplary embodiment of the present inventive concept, a magnification of the first optical part may be substantially different from a magnification of the second optical part.

According to an exemplary embodiment of the present inventive concept, a light exposure device is provided. The light exposure device includes a light exposure head and a head guiding part. The light exposure head is configured to direct light onto a substrate and the head guiding part is configured to guide a movement of the light exposure head. The light exposure head includes a light source, a light modulation part, and a projection optical part. The light source is configured to generate light. The light modulation part is configured to modulate the generated light based on a predetermined exposure pattern. The projection optical part is configured to project the modulated light from the light modulation part onto the substrate as a beam spot array. The projection optical part includes a first optical part, a hole arrangement part, and a second optical part. The first optical part is configured to receive the light from the light modulation part. The first optical part includes a plurality of first lenses. The hole arrangement part is provided between the first optical part and the second optical part. The hole arrangement part is configured to receive the light from the first optical part and to emit the light as the beam spot array. The second optical part is configured to receive the light from the hole arrangement part and to emit the light onto the substrate. The second optical part includes a plurality of second lenses. At least one of the first lenses and the second lenses is a transreflective lens.

In an exemplary embodiment of the present inventive concept, each of the first optical part and the second optical part may include a transreflective lens.

According to an exemplary embodiment of the present inventive concept, a light exposure device is provided. The light exposure device includes a light source, a light modulation part, and a projection optical part. The light source is configured to generate light. The light modulation part is configured to modulate the generated light. The projection optical part is configured to project the modulated light from the light modulation part onto a substrate as a beam spot array. The projection optical part includes a plurality of optical lenses. The light modulation part includes a plurality micro-mirrors and a pattern generating part. The pattern generating part controls tilting angles of each of the plurality of micro-mirrors. At least one of the plurality of optical lenses is a transreflective lens.

### BRIEF DESCRIPTION OF THE DRAWINGS

The above and other features of the present inventive concept will become more apparent by describing in detailed exemplary embodiments thereof with reference to the accompanying drawings, in which:

FIG. 1 is a front view of a maskless light exposure device according to an exemplary embodiment of the present inventive concept;

FIG. 2 is a perspective view illustrating a light exposure head of the maskless light exposure device in FIG. 1;

FIG. 3 is an enlarged perspective view illustrating a light modulation part of the light exposure head in FIG. 2;

FIG. 4 is a cross-sectional view illustrating the light exposure head in FIG. 2;

FIG. 5 is an enlarged cross-sectional view illustrating a portion of a projection optical part of the light exposure head in FIG. 4;

FIG. 6 is an enlarged cross-sectional view illustrating a portion of the projection optical part of the light exposure head according to an exemplary embodiment of the present inventive concept;

FIG. 7 is an enlarged cross-sectional view illustrating a portion of the projection optical part of the light exposure head according to an exemplary embodiment of the present inventive concept;

FIG. 8 is an enlarged cross-sectional view illustrating a portion of the projection optical part of the light exposure head according to an exemplary embodiment of the present inventive concept; and

FIG. 9 is a plan view illustrating a beam array illuminated on a substrate from a maskless light exposure device according to an exemplary embodiment of the present inventive concept.

### DETAILED DESCRIPTION

Hereinafter, exemplary embodiments of the present inventive concept will be described in further detail with reference to the accompanying drawings.

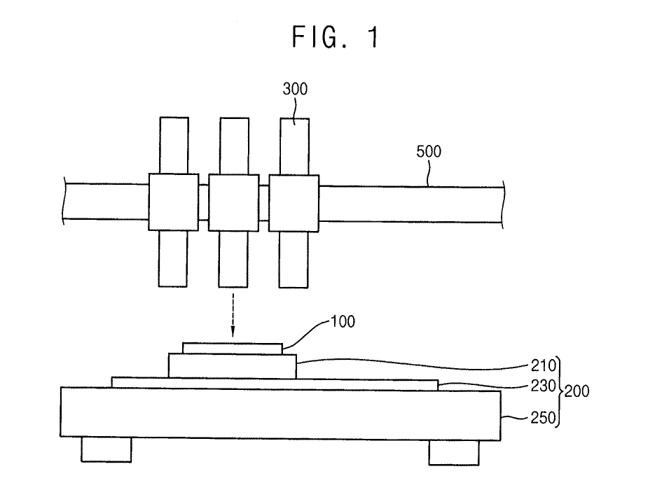

FIG. 1 is a front view of a maskless light exposure device according to an exemplary embodiment of the present inventive concept.

Referring to FIG. 1, a maskless light exposure device according to an exemplary embodiment of the present inventive concept may include a stage 200 and a light exposure head 300. The stage 200 may include a fixing part 210, a guiding part 230, and a body part 250. A substrate 100 may be disposed on the fixing part 210. The guiding part 230 may be configured to guide a movement of the fixing part 230. The maskless light exposure device may further include a head guiding part 500. The head guiding part 500 may be configured to guide a movement of the light exposure head 300.

The fixing part 210 may be configured to fix the substrate 100 when light from the light exposure head 300 is illuminated on the substrate 100.

The guiding part 230 may be configured to guide the fixing part 210 in a horizontal direction or in a vertical direction. For example, the guiding part 230 may be configured to guide the fixing part 210 in a longitudinal direction. For example, the guiding part 230 may be configured to guide the fixing part 210 in a transverse direction.

The body part 250 may support the guiding part 230.

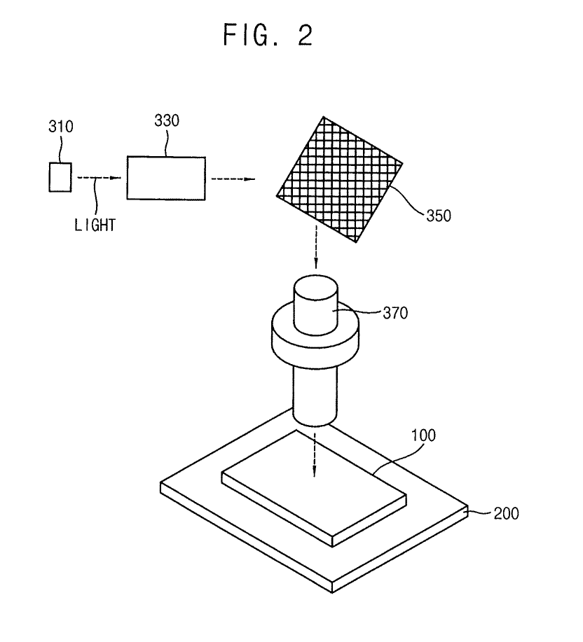

The light exposure head 300 may be configured to illuminate a beam having a desired wavelength on the substrate 100. The light exposure head 300 may be described in detail below with reference to FIG. 2 to FIG. 4.

The head guiding part 500 may be configured to provide a path in which the light exposure head 300 moves. For example, the light exposure head 300 may be configured to move in a horizontal direction along the head guiding part 500.

According to an exemplary embodiment of the present inventive concept, the substrate 100 may be fixed on the stage 200, and the light exposure head 300 may illuminate the beam on the substrate 100 when the light exposure head 300 moves along the head guiding part 500. In an exemplary embodiment of the present inventive concept, the light exposure head 300 may be fixed with respect to the head guiding part 500, and the substrate 100 may be illuminated by the beam from the light exposure head 300 when the guiding part 230 moves the substrate 100 in a desired direction. In an exemplary embodiment of the present inventive concept, both the guiding part 230 and the light exposure head 300 may move in desired directions when the light exposure head 300 illuminates the beam on the substrate 100.

FIG. 2 is a perspective view illustrating a light exposure head of the maskless light exposure device in FIG. 1.

Referring to FIG. 1 and FIG. 2, the light exposure head 300 of the maskless light exposure device may include a light source 310, a light compensation part 330, a light modulation part 350, and a projection optical part 370. The light source 310 may be configured to generate and emit light having a desired wavelength. The light compensation part 330 may be configured to compensate intensity of the light. The light modulation part 350 may be configured to modulate the light as a desired pattern. The projection optical part 370 may be configured to transmit the light on the substrate 100.

The light source 310 may be configured to emit the light. For example, the light source 310 may be configured to emit a laser beam having an ultraviolet wavelength. For example, the light source 310 may include an excimer laser, a diode-pumped solid state laser (“DPSS” laser), etc.

The light compensation part 330 may be configured to compensate the light from the light source 310 to have substantially uniform luminance.

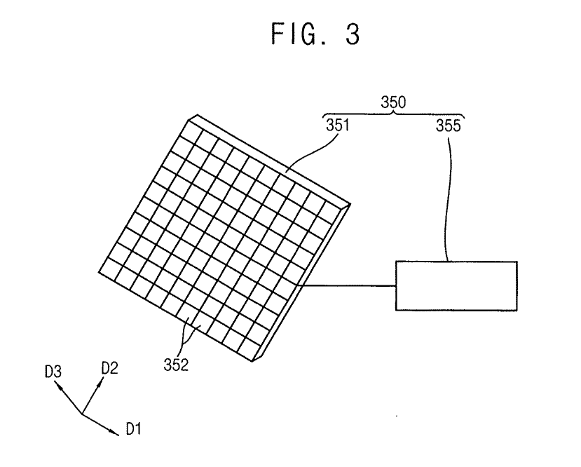

The light modulation part 350 may be configured to spatially modulate the light. For example, the light modulation part 350 may include a spatial light modulator (“SLM”). For example, the light modulation part 350 may include a digital micro-mirror device (“DMD”) having a micro-electro-mechanical systems (“MEMS”), a transparent lead lanthanum zirconate titanate (“transparent PLZT”), a reflective liquid crystal on silicon (“LCos”), etc. In an exemplary embodiment of the present inventive concept, the light modulation part 350 may include the digital micro-mirror device. The light modulation part 350 may be described in detail with reference to FIG. 3.

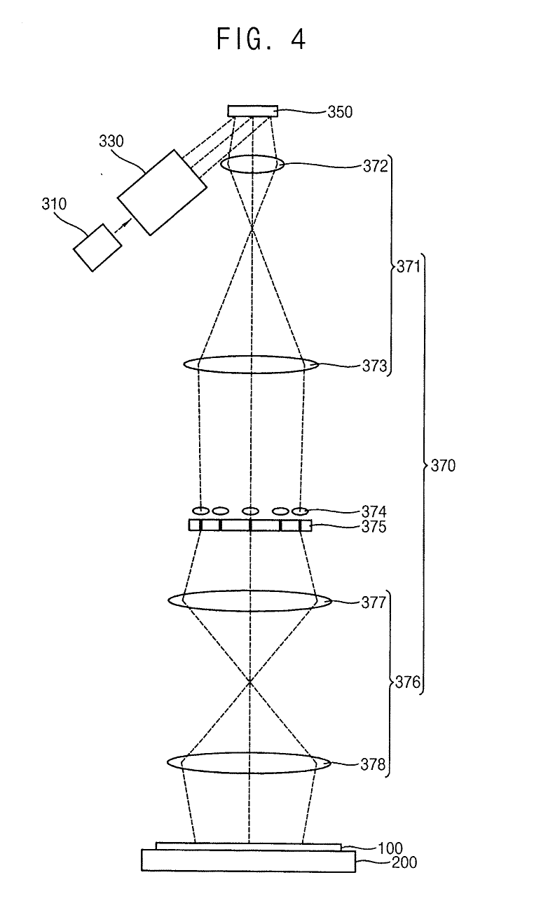

The projection optical part 370 may be configured to transmit the light from the light modulation part 350 on the substrate 100 through a plurality of optical systems therein. For example, the projection optical part 370 may include at least two optical systems. The projection optical part 370 is described in detail below with reference to FIG. 4.

FIG. 3 is an enlarged perspective view illustrating a light modulation part of the light exposure head in FIG. 2.

Referring to FIG. 2 and FIG. 3, the light modulation part 350 may include a plurality of micro-mirrors 352 and a pattern generating part 355. The micro-mirrors 352 may be configured to reflect the light from the light compensation part 330 by desired angles. The pattern generating part 355 may be electrically connected to the micro-mirrors 352. The micro-mirrors 352 may be disposed on memory cells 351. For example, the micro-mirrors 352 may be arranged in a matrix form along a first direction D1 and a second direction D2 which is substantially perpendicular to the first direction D1. The micro-mirrors 352 may be individually controlled by the pattern generating part 355. For example, a portion of the micro-mirrors 352 may be tilted toward a third direction D3 which is substantially perpendicular to the first direction D1 and the second direction D2. For example, a portion of the micro-mirrors 352 may be tilted toward the first direction D1, the second direction D2, and/or the third direction D3 in a three-dimensional space.

For example, when the pattern generating part 355 controls tilting angles of the micro-mirrors 352, the light from the light source 310 may be reflected by the micro-mirrors 352 to illuminate the substrate 100 through the projection optical part 370. For example, when the pattern generating part 355 controls the tilting angles of the micro-mirrors 352, the light from the light source 310 may be reflected by the micro-mirrors 352 not to illuminate the substrate 100.

FIG. 4 is a cross-sectional view illustrating the light exposure head in FIG. 2.

Referring to FIG. 2, FIG. 3 and FIG. 4, the projection optical part 370 may include a first optical part 371, a second optical part 376, and a hole arrangement part therebetween. The hole arrangement part may include a micro-lens array 374 and an aperture array 375.

The first optical part 371 may include at least two optical lenses. For example, the first optical part 371 may include a first incident lens 372 and a first emitting lens 373. The first incident lens 372 may be configured to receive the light from the light modulation part 350. The first emitting lens 373 may be configured to emit the light refracted by the first incident lens 372 to the micro-lens array 374. The first incident lens 372 and the first emitting lens 373 may be configured to refract the light from the light modulation part 350 by a desired magnification or reduction rate. For example, the first optical part 371 may be configured to magnify about 4 times the light from the light modulation part 350.

The micro-lens array 374 may include a plurality of micro-lenses corresponding to the micro-mirrors 352 of the light modulation part 350. For example, when the light modulation part 350 includes the micro-mirrors 352 arranged in a matrix shape of 800×400, the micro-lens array 374 may include the micro-lenses arranged in the matrix shape of 800×400 corresponding to the micro-mirrors 352.

The aperture array 375 may include a plurality of pin holes partially overlapping the micro-lenses. For example, the aperture array 375 may include the pin holes locating at centers of the micro-lenses. A size of each of the pin holes may be, for example, in a range between about 2 μm and about 10 μm.

Light from the aperture array 375 may be a beam spot array having spot shapes such as, e.g., circles, ellipse, etc. The beam spot array may be illuminated on the substrate 100 through the second optical part 376. The beam spot array may include a plurality of spot beams corresponding to the pin holes of the aperture array 375. The spot beams may be spaced apart from one another in a plan view.

The second optical part 376 may include at least two optical lenses. For example, the second optical part 376 may include a second incident lens 377 and a second emitting lens 378. The second incident lens 377 may be configured to receive the beam spot array from the aperture array 375. The second emitting lens 377 may be configured to emit light refracted by the second incident lens 377 on the substrate 100. The second incident lens 377 and the second emitting lens 378 may be configured to refract the beam spot array from the aperture array 375 by a desired magnification or reduction rate. For example, the second optical part 376 may be configured to transmit the beam spot array without a substantial magnification or a reduction.

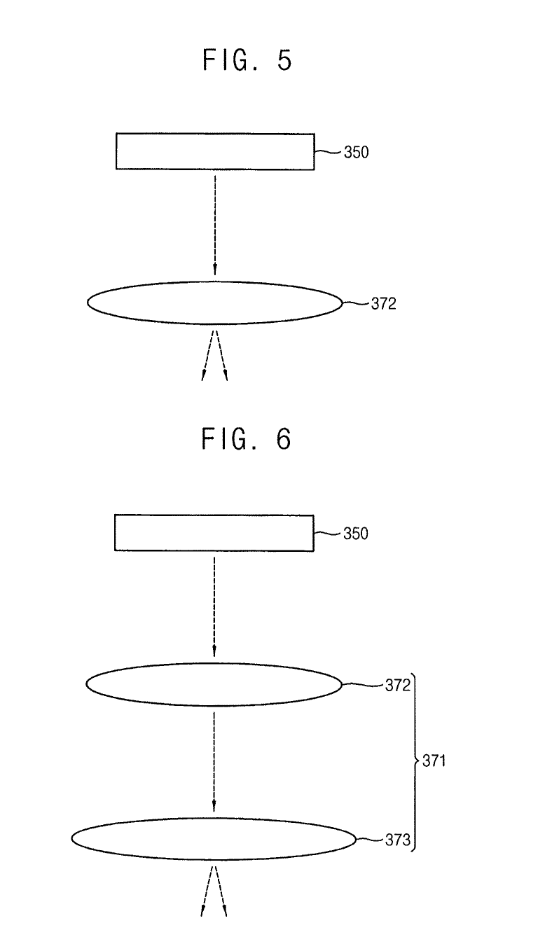

FIG. 5 is an enlarged cross-sectional view illustrating a portion of a projection optical part of the light exposure head in FIG. 4.

Referring to FIG. 4 and FIG. 5, the first incident lens 372 of the light exposure device according to an exemplary embodiment of the present inventive concept may be a transreflective lens. For example, a portion of the light from the light modulation part 350 may pass through the first incident lens 372. The other portion of the light from the light modulation part 350 may be reflected by the first incident lens 372 toward the light modulation part 350 based on an incident angle of the light.

As mentioned above, the first incident lens 372 may be the transreflective lens and thus, an emitting angle of the light from the light modulation part 350 may be adjusted. For example, the emitting angle of the light through the first incident lens 372 may be focused toward a center of the first incident lens 372. Accordingly, an amount of light which is emitted laterally from the first incident lens 372 may be reduced as compared to the use of a transparent lens. In addition, light condensation of the projection optical part 370 may be increased.

FIG. 6 is an enlarged cross-sectional view illustrating a portion of the projection optical part of the light exposure head according to an exemplary embodiment of the present inventive concept.

Referring to FIG. 4 and FIG. 6, the first emitting lens 373 of the light exposure device according to an exemplary embodiment of the present inventive concept may be a transreflective lens. For example, one portion of the light from the first incident lens 372 may pass through the first emitting lens 373. The other portion of the light from the first incident lens 372 may be reflected by the first emitting lens 373 toward the first incident lens 372 based on an incident angle of the light.

As mentioned above, the first emitting lens 373 may be the transreflective lens and thus, an emitting angle of the light from the first incident lens 372 may be adjusted. For example, the emitting angle of the light from the first emitting lens 373 may be focused toward a center of the first emitting lens 373. Accordingly, an amount of light which is emitted laterally from the first emitting lens 373 may be relatively reduced as compared to the use of a transparent lens. In addition, light condensation of the projection optical part 370 may be increased.

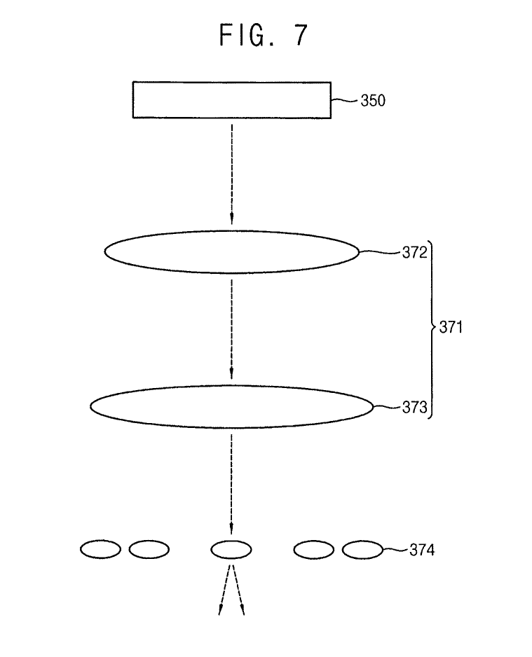

FIG. 7 is an enlarged cross-sectional view illustrating a portion of the projection optical part of the light exposure head according to an exemplary embodiment of the present inventive concept.

Referring to FIG. 4 and FIG. 7, the micro-lenses of the micro-lens array 374 of the light exposure device according to an exemplary embodiment of the present inventive concept may be transreflective lenses. For example, a portion of the light from the first optical part 371 may pass through the micro-lens array 374. The other portion of the light from the first optical part 371 may be reflected by the micro-lens array 374 toward the first emitting lens 373 based on an incident angle of the light.

As mentioned above, the micro-lenses of the micro-lens array 374 may be the transreflective lenses and emitting angles of the light from the first optical part 371 may be adjusted. For example, the emitting angles of the light from the micro-lens array 374 may be focused toward centers of the micro-lenses, respectively. Accordingly, an amount of light which emits laterally from the micro-lens array 374 may be reduced as compared to the use of transparent lenses. In addition, light condensation of the projection optical part 370 may be increased.

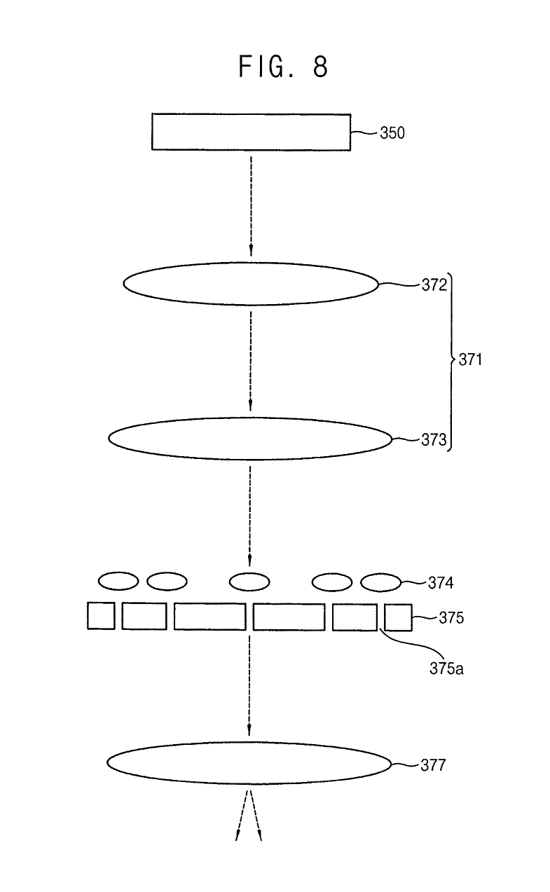

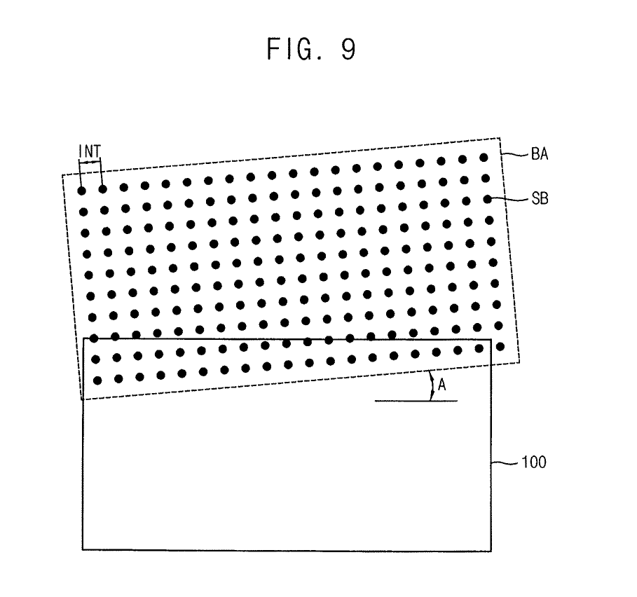

FIG. 8 is an enlarged cross-sectional view illustrating a portion of the projection optical part of the light exposure head according to an exemplary embodiment of the present inventive concept.

Referring to FIG. 4 and FIG. 8, the second incident lens 377 of the light exposure device according to an exemplary embodiment of the present inventive concept may be a transreflective lens. For example, one portion of the light from the micro-lens array 374 and the pin holes 375a of the aperture array 375 may pass through the second incident lens 377. The other portion of the light from the micro-lens array 374 and the pin holes 375a of the aperture array 375 may be reflected by the second incident lens 377 toward the aperture array 375 based on an incident angle of the light. A lower surface of the aperture array 375 may be reflective.

As mentioned above, the second incident lens 377 may be the transreflective lens and thus, an emitting angle of the light from the aperture array 375 may be adjusted. For example, the emitting angle of the light from the second incident lens 377 may be focused toward a center of the second incident lens 377. Accordingly, an amount of light which emits laterally from the second incident lens 377 may be reduced as compared to the use of a transparent lens. In addition, light condensation of the projection optical part 370 may be increased.

According to an exemplary embodiment of the present inventive concept, one of the optical lenses among the first optical part 371, the micro-lens array 374, and the second optical part 376 may be a transreflective lens. However, the projection optical part 370 of the light exposure head of the maskless light exposure device is not limited thereto. For example, in an exemplary embodiment of the present inventive concept, more than one lens of the optical lenses among the first optical part 371, the micro-lens array 374, and the second optical part 376 may be transreflective lenses.

FIG. 9 is a plan view illustrating a beam array illuminated on a substrate from a maskless light exposure device according to an exemplary embodiment of the present inventive concept.

Referring to FIG. 9, the maskless light exposure device according to an exemplary embodiment of the present inventive concept may illuminate the beam spot array BA on the substrate 100. The beam spot array BA may include a plurality of spot beams SB. The spot beams SB may be spaced apart from one another by a desired interval INT. For example, the interval INT between the spot beams SB may be in a range between about 10 μm and about 100 μm. Each of the spot beams SB may have, e.g., a circular shape, an elliptical shape, etc. A full width at half maximum of the spot beams SB may be in a range between about 1 μm and about 3 μm. The beam spot array BA may be tilted with respect to the substrate 100 by a desired angle A in a plan view. Accordingly, a resolution of the maskless light exposure device may be increased.

As mentioned above, according to exemplary embodiments of the present inventive concept of the maskless light exposure device, the projection optical part may include a transreflective lens, illumination beam toward a desired direction may be condensed, and thus light condensation of the light exposure device may be increased.

The foregoing is illustrative of exemplary embodiments of the present inventive concept and the disclosure should not be construed as limiting. Although a few exemplary embodiments of the present inventive concept have been described, it will be understood that various modifications in form and details may be made therein without departing from the spirit and scope of the present inventive concept.

What is claimed is:

1. A light exposure device, comprising:
a light source configured to generate light;
a light modulation part configured to modulate the generated light based on a predetermined exposure pattern; and
a projection optical part configured to project the modulated light from the light modulation part onto a substrate as a beam spot array, the projection optical part comprising:
a first optical part configured to receive the modulated light from the light modulation part, the first optical part comprising a plurality of first lenses;
a hole arrangement part provided between the first optical part and a second optical part, the hole arrangement part being configured to receive the light from the first optical part and to emit the received light as the beam spot array; and
the second optical part configured to receive the light from the hole arrangement part and to emit the received light onto the substrate, the second optical part comprising a plurality of second lenses,
wherein at least one of the first lenses and the second lenses is a transreflective lens.

2. The light exposure device of claim 1, wherein the light modulation part comprises a digital micro-mirror device.

3. The light exposure device of claim 2, wherein the digital micro-mirror device comprises:
a plurality of micro-mirrors arranged in a first direction and a second direction crossing the first direction; and
a pattern generating part configured to control a reflective angle of the micro-mirrors.

4. The light exposure device of claim 3, wherein the hole arrangement part comprises:
a micro-lens array comprising a plurality of micro-lenses corresponding to the micro-mirrors of the digital micro-mirror device; and
an aperture array comprising a plurality of pin holes partially overlapping the micro-lenses.

5. The light exposure device of claim 4, wherein each of the pin holes is greater than about 2 μm and smaller than about 10 μm in size.

6. The light exposure device of claim 4, wherein a number of the micro-mirrors is equal to a number of the micro-lenses.

7. The light exposure device of claim 1, wherein each of the first optical part and the second optical part comprises a transreflective lens.

8. The light exposure device of claim 1, wherein the first optical part comprises:
a first incident lens configured to receive the modulated light from the light modulation part and to refract the received light; and
a first emitting lens configured to transmit the refracted light toward the hole arrangement part.

9. The light exposure device of claim 8, wherein at least one of the first incident lens and the first emitting lens is a transreflective lens.

10. The light exposure device of claim 1, wherein the second optical part comprises:
a second incident lens configured to receive the light from the hole arrangement part and to refract the received light; and
a second emitting lens configured to transmit the refracted light toward the substrate.

11. The light exposure device of claim 10, wherein at least one of the second incident lens and the second emitting lens is a transreflective lens.

12. The light exposure device of claim 1, wherein the beam spot array comprises a plurality of spot beams spaced apart from one another.

13. The light exposure device of claim 12, wherein each of the plurality of spot beams has a substantially circular shape having a full width at half maximum in a range between about 1 μm and about 3 μm.

14. The light exposure device of claim 12, wherein each of the plurality of spot beams is spaced apart from one another by a distance in a range between 10 μm and about 100 μm.

15. The light exposure device of claim 1, wherein the beam spot array is tilted with respect to the substrate in a plan view.

16. The light exposure device of claim 1, further comprising a light compensation part provided between the light source and the light modulation part, the light compensation part being configured to compensate the light from the light source such that the light has a substantially uniform luminance.

17. The light exposure device of claim 1, further comprising:
a fixing part on which the substrate is disposed; and
a guiding part configured to move the fixing part in a horizontal or a vertical direction.

18. The light exposure device of claim 1, wherein a magnification of the first optical part is substantially different from a magnification of the second optical part.

19. A light exposure device, comprising:
a light exposure head configured to direct light onto a substrate; and
a head guiding part configured to guide a movement of the light exposure head,
the light exposure head comprising:
a light source configured to generate light;
a light modulation part configured to modulate the generated light based on a predetermined exposure pattern; and
a projection optical part configured to project the modulated light from the light modulation part onto the substrate as a beam spot array, the projection optical part comprising:
a first optical part configured to receive the light from the light modulation part, the first optical part comprising a plurality of first lenses;
a hole arrangement part provided between the first optical part and a second optical part, the hole arrangement part being configured to receive the light from the first optical part and to emit the light as the beam spot array;
the second optical part configured to receive the light from the hole arrangement part and to emit the light onto the substrate, the second optical part comprising a plurality of second lenses,
wherein at least one of the first lenses and the second lenses is a transreflective lens.

20. A light exposure device, comprising:
a light source configured to generate light;
a light modulation part configured to modulate the generated light; and
a projection optical part configured to project the modulated light from the light modulation part onto a substrate as a beam spot array, the projection optical part comprising a plurality of optical lenses,
wherein the light modulation part comprises a plurality micro-mirrors and a pattern generating part for controlling tilting angles of each of the plurality of micro-mirrors, and
wherein at least one of the plurality of optical lenses is a transreflective lens.
